(19) United States
(12) Patent Application Publication
(10) Pub. No.: US 2012/0305295 A1
(43) Pub. Date: Dec. 6, 2012

(54) THERMOSETTING COMPOSITION

(75) Inventors: Kazuya Kimura, Minato-ku (JP); Kazuhiko Ooga, Minato-ku (JP); Kiichiro Miura, Minato-ku (JP)

(73) Assignee: SHOWA DENKO K.K., Minato-ku, Tokyo (JP)

(21) Appl. No.: 13/576,893

(22) PCT Filed: Feb. 3, 2010
(86) PCT No.: PCT/JP2011/051267

§ 371 Date: Aug. 2, 2012

(30) Foreign Application Priority Data
Feb. 3, 2010 (JP) 2010-022212

(51) Int. Cl. C09D 175/04; H05K 3/22; H05K 1/02

(52) U.S. Cl. 174/254; 524/590; 427/98.4

(57) ABSTRACT

It is an object of the present invention to provide a thermosetting composition which is excellent in low warpage properties and long-term electrical insulation reliability and is capable of forming an insulating film that inhibits disconnection of wiring of a flexible wiring board. The thermosetting composition of the present invention is a thermosetting composition for forming an insulating film, by curing the composition, on a flexible wiring board comprising a wiring pattern formed on a flexible substrate, and is characterized in that a cured product obtained by curing the composition has a tensile elastic modulus of 0.5 to 2.0 GPa.

### TECHNICAL FILED

The present invention relates to the following matters:

(1) a thermosetting composition capable of forming an insulating film (cured product) that inhibits disconnection of a flexible wiring board,

(2) a cured product obtained by thermally curing the composition,

(3) a flexible wiring board wherein a surface on which a wiring pattern has been formed is at least partially covered with the cured product, and

(4) a process for producing such a flexible wiring board.

### BACKGROUND ART

As a resist ink for forming a protective film or the like on a conventional wiring board, a technique disclosed in Japanese Patent Laid-Open Publication No. 2003-198105 (patent literature 1) to meet low warpage properties can be mentioned. That is to say, a curable composition that forms a cured film having a tensile elastic modulus of not more than 0.5 GPa has been used. In this case, however, there is a problem that the protection performance to inhibit disconnection of wiring of the wiring board is not satisfactory.

Disconnection of wiring is caused by repeated flexes of a flexible wiring board, vibration, etc. In the circumstances where the line width exceeds 20 μm as in a conventional wiring board, the strength of the wiring itself does not have great influence on whether disconnection takes place or not. However, with downsizing of electrical equipments, the line width has become as narrow as not more than 20 μm, and the wiring itself has insufficient strength, resulting in a problem of occurrence of disconnection. On this account, a resist ink capable of forming a protective film which can effectively inhibit disconnection of wiring has been desired. Moreover, in order to prevent malfunction of a flexible wiring board, the protective film is required to have electrical insulation properties.

As a method to inhibit disconnection of a wiring board, there is a method of using a solder resist having a tensile elastic modulus of 2 to 3 GPa, as disclosed in Japanese Patent Laid-Open Publication No. 2002-185110 (patent literature 2). However, this method is a method to inhibit disconnection in uses in which flexibility is not required for a substrate of a wiring board, such as a semiconductor package.

As a method to improve a balance between low warpage properties (these are determined by a balance between rigidity of a wiring board and flexibility of a protective film, thicknesses of the wiring board and the protective film, etc., and when a protective film is more flexible than a flexible wiring board by synthesizing them, low warpage properties are achieved) and folding endurance of a flexible wiring board, a technique disclosed in Japanese Patent Laid-Open Publication No. 2007-279489 (patent literature 3) can be mentioned. This technique is a method of using a curable composition capable of forming a cured product having a tensile elastic modulus of 0.5 to 1.5 GPa. The curable composition is a photosensitive resin composition requiring a photoinitiator. In the case of the photosensitive composition, an exposure step to form a protective film is essential, and therefore, the steps for producing a flexible wiring board having a protective film become complicated. Further, a protective film is formed on, for example, only wiring formed on a flexible wiring board, and therefore, when a development step is carried out for the purpose of pattering, ion contamination with sodium ion or the like contained in a developing solution takes place. As a result, electrical insulation properties of the flexible wiring board are sometimes deteriorated.

It is predicted that with development of a semi-additive process, the line space of a flexible wiring board will be further narrowed (e.g., pitch of not more than 20 μm) in future. Therefore, development of a resist ink (curable composition) which can inhibit disconnection of a wiring board as previously described and can form a flexible cured film is desired.

On the other hand, a curable composition containing a compound having an epoxy group which undergoes curing reaction (e.g., epoxy resin) and a compound having a functional group which reacts with the epoxy group is used for a resist. Here, when polyurethane having such a functional group and a carbonate bond is paid attention, a compound disclosed in Japanese Patent Laid-Open Publication No. 2003-198105 (patent literature 1) can be given as polyurethane having an acid anhydride group and/or an isocyanate group, and a carbonate bond. As polyurethanes having a carboxyl group and a carbonate bond, there can be mentioned compounds disclosed in Japanese Patent Laid-Open Publication No. 2006-117922 (patent literature 4), Japanese Patent Laid-Open Publication No. 2007-39673 (patent literature 5) and Japanese Patent Laid-Open Publication No. 2008-201847 (patent literature 6).

In any of these literatures, however, inhibition of wiring disconnection of a flexible wiring board is not described at all.

### PRIOR ART

### Patent Literature

Patent Literature 1: Japanese Patent Laid-Open Publication No. 2003-198105
Patent Literature 2: Japanese Patent Laid-Open Publication No. 2002-185110
Patent Literature 3: Japanese Patent Laid-Open Publication No. 2007-279489
Patent Literature 4: Japanese Patent Laid-Open Publication No. 2006-117922
Patent Literature 5: Japanese Patent Laid-Open Publication No. 2007-39673
Patent Literature 6: Japanese Patent Laid-Open Publication No. 2008-201847

### SUMMARY OF THE INVENTION

### Subject to be Solved by the Invention

It is an object of the present invention to provide a thermosetting composition capable of forming an insulating film (cured product) having an effect of inhibiting disconnection of wiring of a flexible wiring board.

More particularly, it is an object of the present invention to provide a thermosetting composition which is excellent in low warpage properties and long-term electrical insulation reliability and is capable of forming an insulating film that inhibits disconnection of wiring of a flexible wiring board.

### Means for Solving the Subject

In order to solve the above problems, the present inventors have studied repeatedly. As a result, they have found that the following effects are obtained by a thermosetting composition capable of forming a cured product having a tensile elastic modulus of a specific range, and they have accomplished the present invention.

(1) Disconnection of wiring of a flexible wiring board can be inhibited.

(2) Warpage of a flexible wiring board occurring when the thermosetting composition is cured is low.

(3) An insulating film (cured product) obtained by curing the thermosetting composition is excellent also in long-term electrical insulation properties.

That is to say, the present invention (I) is a thermosetting composition for forming an insulating film, by curing the composition, on a flexible wiring board comprising a wiring pattern formed on a flexible substrate, wherein a cured product obtained by curing the composition has a tensile elastic modulus of 0.5 to 2.0 GPa.

The present invention (II) is a cured product obtained by thermally curing the thermosetting composition of the present invention (I).

The present invention (III) is a process for producing a flexible wiring board having an insulating film, which has the steps of applying the thermosetting composition of the present invention (I) onto a wiring pattern of a flexible wiring board comprising the wiring pattern formed on a flexible substrate, by a printing method to form a printed film on the pattern, and thermally curing the printed film to form an insulating film from the printed film.

More particularly, the present invention relates to the following matters.

[1] A thermosetting composition for forming an insulating film, by curing the composition, on a flexible wiring board comprising a wiring pattern fouled on a flexible substrate, wherein a cured product obtained by curing the composition has a tensile elastic modulus of 0.5 to 2.0 GPa.

[2] The thermosetting composition as described in [1], wherein the flexible wiring board has a line width of not more than 20 μm.

[3] The thermosetting composition as described in [1] or [2], which contains polyurethane (a) having a functional group having reactivity to an epoxy group and a carbonate bond, inorganic fine particles and/or organic fine particles (b) and a compound (c) having two or more epoxy groups in one molecule.

[4] The thermosetting composition as described in [3], wherein the functional group having reactivity to an epoxy group in the polyurethane (a) is at least one functional group selected from the group consisting of a carboxyl group, an isocyanate group, a hydroxyl group and a cyclic acid anhydride group.

[5] The thermosetting composition as described in [3] or [4], wherein the compound (c) has an aromatic ring structure and/or an alicyclic structure.

[6] The thermosetting composition as described in [5], wherein the compound (c) has a tricyclodecane structure and an aromatic ring structure.

[7] A cured product obtained by thermally curing the thermosetting composition as described in any one of [1] to [6].

[8] A flexible wiring board having an insulating film, wherein a wiring pattern-side surface of a flexible wiring board comprising a wiring pattern formed on a flexible substrate is at least partially covered with an insulating film composed of the cured product as described in [7].

[9] A process for producing a flexible wiring board having an insulating film, having the steps of:

applying the thermosetting composition as described in any one of [1] to [6] onto a wiring pattern of a flexible wiring board comprising the wiring pattern formed on a flexible substrate, by a printing method to form a printed film on the pattern, and heating the printed film at 80 to 130° C. to cure the film and to thereby form an insulating film from the printed film.

[10] The process for producing a flexible wiring board having an insulating film as described in [9], wherein the wiring pattern has been subjected to tin plating.

### Effect of the Invention

A flexible wiring board using an insulating film formed from the thermosetting composition of the present invention as a protective film of wiring is inhibited from disconnection of wiring.

Further, a flexible wiring board on which the thermosetting composition has been printed exhibits low warpage when the composition is cured, and an insulating film (cured product) obtained by curing the thermosetting composition is excellent in long-term electrical insulation properties.

### EMBODIMENT FOR CARRYING OUT THE INVENTION

The present invention is described in detail hereinafter.

First, the present invention (I) is described.

[Present Invention (I)]

The present invention (I) is a thermosetting composition characterized in that a cured product of the composition has a tensile elastic modulus of 0.5 to 2.0 GPS, and the composition is used for forming an insulating film on a flexible wiring board by curing the composition. Especially when the thermosetting composition of the present invention (I) is used for forming an insulating film on a flexible wiring board having a line width of not more than 20 plain which disconnection of wiring is liable to take place, its effects are remarkably exerted.

[Thermosetting component]

Examples of thermosetting components of the thermosetting composition include phenol resin, epoxy resin, melamine resin, urea resin, unsaturated polyester resin, alkyd resin, polyurethane and thermosetting polyimide. These may be used in combination of two or more kinds. From such single resins and resin mixtures obtained by combining plural resins, a resin or a mixture capable of forming a cured product having a tensile elastic modulus of 0.5 to 2.0 GPa is properly selected and can be applied to the present invention.

The thermosetting composition of the present invention may contain the later-described other components in addition to the above thermosetting component. Also in this case, a combination is properly selected so that a cured product obtained by curing the thermosetting composition may have a tensile elastic modulus of the above range.

[Tensile Elastic Modulus of Cured Product Obtained by Curing Thermosetting Composition]

In the present invention, the tensile elastic modulus of the cured product is a numerical value obtained by evaluating a strip cut out from the cured product and having a width of 10 mm and a length of 60 mm, a chuck-to-chuck distance of 30 mm and a pull rate of 5 mm/min by the use of a tensile tester under the conditions of a temperature of 25° C. (e.g., equipment: small table-top tester EZGraph manufactured by Shimadzu Corporation).

The present inventors have studied tensile moduli of cured products obtained from various thermosetting compositions, and as a result, they have found that in the case where the tensile elastic modulus is in the range of 0.5 to 2.0 GPa, use of the aforesaid cured product as an insulating film of wiring of a flexible wiring board inhibits disconnection of the wiring and makes warpage sufficiently low when the thermosetting composition is cured.

The flexible wiring board is constituted of a substrate material, metal wiring and a cured product such as a solder resist. If there is no cured product, the metal wiring is exposed outside on the wiring board, and when a flexural load is applied to the wiring board, the wiring is cracked, sometimes resulting in disconnection.

In the case where the tensile elasticmodulus of the cured product is less than 0.5 GPa, if a flexural load is applied to the flexible wiring board, the wiring is cracked and this leads to disconnection even if the cured product is used as an insulating film (protective film) of metal wiring. The reason is that the cured product is soft and has no ability to protect the metal wiring.

On the other hand, in the case where the tensile elastic modulus of the curedproduct is not less than 0.5 GPa, the metal wiring protection ability of the cured product is enhanced, and even if a flexural load is applied to the wiring board, cracking hardly takes place in the wiring.

However, if the tensile elastic modulus of the cured product is more than 2.0 GPa, hardness of the cured product exceeds hardness of the flexible wiring board though the cured product has metal wiring protection ability, and negative influence is exerted on the flexibility and the low warpage properties of the flexible wiring board.

From the above, the tensile elastic modulus of the cured product is 0.5 to 2.0 GPa in the present invention. From the viewpoints of wiring protection ability and influence on the flexibility and the low warpage properties of the flexible wiring board, the tensile elastic modulus of the cured product is preferably 0.7 to 1.5 PGa.

The thermosetting composition of the present invention capable of forming a cured product having excellent wiring protection ability and exerting no negative influence on the flexibility and the low warpage properties of the flexible wiring board as described above is useful as an excellent solder resist ink used for the protection of wiring.

[Preferred Components Contained in Thermosetting Composition]

From the viewpoint that excellent low warpage properties and long-term insulation properties are also achieved in addition to the inhibition of disconnection of wiring, the thermosetting composition of the present invention (I) preferably contains polyurethane (a) having a functional group having reactivity to an epoxy group and a carbonate bond (also referred to as “polyurethane (a)” simply hereinafter), inorganic fine particles and/or organic fine particles (b) and a compound (c) having two or more epoxy groups in one molecule (also referred to as a “compound (c)” simply hereinafter). These components are described below.

<Polyurethane (a)>

The polyurethane (a) is not specifically restricted provided that it is polyurethane having a functional group having reactivity to an epoxy group and a polycarbonate bond. The polyurethane may be used singly or in combination of two or more kinds.

The “functional group having reactivity to an epoxy group” is not specifically restricted provided that it is a functional group which can react with the later-described compound (c) having two or more epoxy groups in one molecule. The reaction between the polyurethane (a) and the compound (c) is curing reaction, and a cured product formed by the reaction is preferable as an insulating film to protect wiring of a flexible wiring board or the like.

Examples of the functional groups having reactivity to an epoxy group include a carboxyl group, an isocyanate group, a hydroxyl group and a cyclic acid anhydride group. When the reactivity to the compound (c) is taken into account, preferred functional groups among them are a carboxyl group, an isocyanate group and a cyclic acid anhydride group. When a balance between storage stability of the polyurethane (a) and reactivity of the compound (c) is taken into account, more preferred functional groups are a carboxyl group and a cyclic acid anhydride group, and a particularly preferred functional group is a carboxyl group.

When an acid anhydride group forms a part of a cyclic structure, the above-mentioned cyclic acid anhydride group indicates the cyclic structure. The polyurethane having such a cyclic acid anhydride group and a carbonate bond is, for example, polyurethane having an imide bond and having an acid anhydride group and a carbonate bond, which is described in [0023] to [0067] and Example 1 of Japanese Patent Laid-Open Publication No. 2003-198105.

Polyurethane having a carboxyl group, an isocyanate group or a hydroxyl group (also referred to as “polyurethane A” hereinafter) can be prepared by, for example, the following process.

The polyurethane A can be synthesized by reacting a (poly)carbonate polyol, a diisocyanate compound and a carboxyl group-containing diol in the presence or absence of a publicly known urethanation catalyst, such as dibutyl tin dilaurate, using a solvent such as diethylene glycol diethyl ether or γ-butyrolactone or a mixed solvent containing it.

The solvent which can be used for the synthesis of the polyurethane A is not specifically restricted provided that it can dissolve synthesis raw materials for the polyurethane A and can also dissolve the polyurethane A. Examples of such solvents include not only the aforesaid diethylene glycol diethyl ether and γ-butyrolactone but also diethylene glycol monoethyl ether acetate, diethylene glycol butyl methyl ether, tripropylene glycol dimethyl ether, triethylene glycol dimethyl ether, diethylene glycol monoethyl ether, butyl phenyl ether, amyl phenyl ether, diethylene glycol monoisopropyl ether, diethylene glycol monoisobutyl ether and dipropylene glycol monopropyl ether.

As the synthesis raw materials for the polyurethane A, a polyol other than the (poly)carbonate polyol and the carboxyl group-containing diol, a monohydroxyl compound and a monoisocyanate compound may be further used, when needed.

It is preferable that the above reaction is carried out in the absence of a catalyst because property values (e.g., electrical insulation properties) of a cured product finally obtained by thermally curing the thermosetting composition of the present invention (I) are enhanced in the practical use. Even in the case of the reaction in the absence of a catalyst, the reaction proceeds sufficiently because reactivity of alcohol to isocyanate or reactivity of alcohol to alcohol is high.

((Poly)Carbonate Polyol)

A (poly)carbonate polyol that is one of synthesis raw materials for the polyurethane A is not specifically restricted provided that it is a compound having one or more carbonate bonds and two or more alcoholic hydroxyl groups in a molecule. Examples thereof include (poly)carbonate diols having two hydroxyl groups in one molecule, and (poly)carbonate trials and (poly)carbonate tetraols having three or more hydroxyl groups in one molecule. The number of carbonate bonds in the (poly)carbonate polyol is usually 50 or less, and the number of alcoholic hydroxyl groups is usually 2, but a (poly)carbonate polyol having 3 or 4 alcoholic hydroxyl groups can be also used.

The (poly)carbonate polyol can be obtained by using, as a raw material, a diol or a polyol mixture containing a diol as amain component and reacting this with a carbonic acid ester or phosgene. For example, when a diol only is used as a raw material for the (poly)carbonate polyol, which is reacted with the carbonic acid ester or phosgene, a (poly)carbonate diol is prepared, and its structure is represented by the following formula (1).

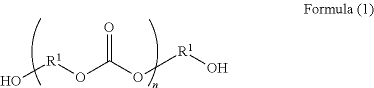

In the formula (1), R¹ of (n+1) are each independently a residue (alkylene group) obtained by removing hydroxyl groups from the corresponding diol, n is a natural number, and n is usually an integer of 3 to 50.

The (poly)carbonate polyol represented by the formula (1) can be produced specifically by using, as a raw material, a diol compound such as 1,4-butanediol, 1,5-pentanediol, 1,6-hexanediol, 3-methyl-1,5-pentanediol, 1,8-octanediol, 1,3-cyclohexanedimethanol, 1,4-cyclohexanedimethanol, 1,9-nonanediol, 2-methyl-1,8-octanediol, 2-ethyl-4-butyl-1,3-propanediol, 2,4-diethyl-1,5-pentanediol, 1,10-decanediol and 1,2-tetradecanediol.

The (poly)carbonate polyol may be (poly)carbonate polyol having plural kinds of alkylene groups in its structure (copolymerized (poly)carbonate polyol). From the viewpoint of prevention of crystallization of polyurethane A in the above solvent for synthesis reaction, use of the copolymerized (poly)carbonate polyol is advantageous in many cases. Taking into account solubility into reaction solvents (diethylene glycol diethyl ether, γ-butyrolactone, etc.) for synthesis of polyurethane A, it is preferable to use (poly)carbonate polyol having a branched structure and having a hydroxyl group at the end of the branched chain.

The (poly)carbonate polyols described above may be used singly or in combination of two or more kinds.

(Diisocyanate Compound)

The diisocyanate compound that is one of synthesis raw materials for the polyurethane A is not specifically restricted provided that it is a compound having two isocyanate groups.

Examples of the diisocyanate compounds include 1,4-cyclohexane diisocyanate, isophorone diisocyanate, methylenebis(4-cyclohexyl isocyanate), 1,3-bis(isocyanatomethyl)cyclohexane, 1,4-bis(isocyanatomethyl)cyclohexane, 2,4-tolylene diisocyanate, 2,6-tolylene diisocyanate, diphenylmethane-4,4′-diisocyanate, 1,3-xylylene diisocyanate, 1,4-xylylene diisocyanate, a biuret form of isophorone diisocyanate, a biuret form of hexamethylene diisocyanate, an isocyanurate form of isophorone diisocyanate, an isocyanurate form of hexamethylene diisocyanate, lysine triisocyanate, lysine diisocyanate, hexamethylene diisocyanate, 2,4,4-trimethylhexamethylene diisocyanate, 2,2,4-trimethylhexamethylene diisocyanate and norbornane diisocyanate.

From the viewpoint that the electrical insulation performance of the later-described cured product of the present invention (II) is highly maintained, 1,4-cyclohexane diisocyanate, isophorone diisocyanate, methylenebis(4-cyclohexyl isocyanate), 1,3-bis(isocyanatomethyl)cyclohexane, 1,4-bis(isocyanatomethyl)cyclohexane, diphenylmethane-4,4′-diisocyanate, 1,3-xylylene diisocyanate, 1,4-xylylene diisocyanate, 2,4,4-trimethylhexamethylene diisocyanate, 2,2,4-trimethylhexamethylene diisocyanate and norbornane diisocyanate are preferable among them, and methylenebis(4-cyclohexyl isocyanate), diphenylmethane-4,4′-diisocyanate and norbornane diisocyanate are more preferable.

The diisocyanate compounds described above may be used singly or in combination of two or more kinds.

(Carboxyl Group-Containing Diol)

The carboxyl group-containing diol that is one of synthesis raw materials for the polyurethane A is not specifically restricted provided that it is a compound having two alcoholic hydroxyl groups and one or more carboxyl groups in a molecule. The number of the carboxyl groups is usually 1.

Examples of the carboxyl group-containing diols include dimethylolpropionic acid, 2,2-dimethylolbutanoic acid and N,N-bis(hydroxyethyl)glycine. Of these, dimethylolpropionic acid and 2,2-dimethylolbutanoic acid are particularly preferable from the viewpoint of solubility in a synthesis reaction solvent for synthesis of the polyurethane A. These carboxyl group-containing diols may be used singly or in combination of two or more kinds.

(Polyol Other than (Poly)Carbonate Polyol and Carboxyl Group-Containing Diol)

As a synthesis raw material for the polyurethane A, a polyol other than the (poly)carbonate polyol and the carboxyl group-containing diol (also referred to as a “polyol” simply hereinafter) can be used, when needed, as previously described. By the use of the polyol as a synthesis raw material for the polyurethane A, molecular weight and viscosity of the polyurethane A can be controlled.

The polyol is not specifically restricted provided that it is a compound other than the (poly)carbonate polyol and the carboxyl group-containing diol and is a compound having two or more alcoholic hydroxyl groups. The number of the alcoholic hydroxyl groups in the polyol is usually 6 or less.

Examples of the polyols include diols, such as 1,4-butanediol, 1,5-pentanediol, 1,6-hexanediol, 3-methyl-1,5-pentanediol, 1,8-octanediol, 1,3-cyclohexanedimethanol, 1,4-cyclohexanedimethanol, 1,9-nonanediol, 2-methyl-1,8-octanediol, 2-ethyl-4-butyl-1,3-propanediol, 2,4-diethyl-1,5-pentanediol, 1,10-decanediol and 1,2-tetradecanediol, and compounds having 3 or more alcoholic hydroxyl groups in one molecule, such as trimethylolpropane, trimethylolethane, glycerol and pentaerythritol.

These are compounds which can be used as synthesis raw materials for the (poly)carbonate polyol, and in general, a raw material polyol remaining in the preparation of a (poly)carbonate polyol can be used for the synthesis of the polyurethane A as it is or by further adding a polyol.

The polyols described above may be used singly or in combination of two or more kinds.

(Monohydroxyl Compound)

As a synthesis raw material for the polyurethane A, a monohydroxylcompoundcanbeused, when needed, as previouslydescribed. By adding the monohydroxyl compound during the synthesis reaction for the polyurethane A, the synthesis reaction can be terminated.

The monohydroxyl compound is not specifically restricted provided that it is a compound which has one alcoholic hydroxyl group in a molecule and does not have a substituent (e.g., amino group) having higher reactivity to an isocyanate group than the alcoholic hydroxyl group.

Specific examples of the monohydroxyl compounds include methanol, ethanol, n-propanol, isopropanol, n-butanol, isobutanol, sec-butanol, t-butanol, ethylene glycol monoethyl ether, diethylene glycol monoethyl ether, diethylene glycol monoisopropyl ether, diethylene glycol monoisobutyl ether and dipropylene glycol monopropyl ether.

These monohydroxyl compounds may be used singly or may be used in combination of two or more kinds.

(Monoisocyanate Compound)

As a synthesis raw material for the polyurethane A, a monoisocyanate compound can be used, when needed, as previously described. By the use of the monoisocyanate compound as a synthesis raw material for the polyurethane A, molecular weight of the polyurethane A can be controlled.

The monoisocyanate compound is not specifically restricted provided that it is a compound having one isocyanate group. Examples thereof include cyclohexyl isocyanate, octadecyl isocyanate, phenyl isocyanate and toluoyl isocyanate.

When discoloration resistance of the thermosetting composition of the present invention (I) during heating is taken into account, cyclohexyl isocyanate and octadecyl isocyanate are preferable.

(Synthesis of Polyurethane a Having Carboxyl Group, Isocyanate Group or Hydroxyl Group)

As previously described, the polyurethane A can be synthesized by reacting a (poly)carbonate polyol, a diisocyanate compound, a carboxyl group-containing diol, and if necessary, a polyol other than the (poly)carbonate polyol and the carboxyl group-containing diol, a monohydroxyl compound and a monoisocyanate compound in the presence or absence of a publicly known urethanation catalyst using a solvent such as diethylene glycol diethyl ether or γ-butyrolactone.

The order of introduction of these raw materials into a reactor is not specifically restricted, but in usual, the (poly)carbonate polyol, the carboxyl group-containing diol, and if necessary, the polyol are introduced first, and they are dissolved in a solvent. The temperature of the solution is set at 20 to 140° C., more preferably 60 to 120° C., and to the solution, the diisocyanate compound is dropwise added, followed by reacting these raw materials for the polyurethane A at 50 to 160° C., more preferably 60 to 150° C.

The molar ratio of the raw materials introduced is controlled according to the desired molecular weight and acid value of the polyurethane A. Although the molecular weight can be controlled by the molar ratio of the raw materials introduced, the reaction temperature and the reaction time, it can be controlled also by the use of the monohydroxyl compound. That is to say, at the time when the polyurethane A is presumed to have the desired number-average molecular weight (or the desired number-average molecular weight is presumed to be approached), the monohydroxyl compound is added for the purpose of capping the isocyanate end group of polyurethane that is growing owing to the reaction of the synthesis raw materials and thereby inhibiting further increase of the number-average molecular weight. This timing can be derived by measuring number-average molecular weights of polyurethanes A obtained by changing the reaction time under the fixed conditions of the raw materials and the reaction temperature and keeping the data.

When the monohydroxyl compound is used, the number of isocyanate groups in the diisocyanate compound may be smaller than or identical with or larger than the total number of all the hydroxyl groups in the (poly)carbonate polyol, the carboxyl group-containing diol and the polyol. The reason is that if the end is capped with the monohydroxyl compound, the reaction does not proceed any more.

When the monohydroxyl compound is used in excess, an unreacted monohydroxyl compound remains, and in this case, the excessive monohydroxyl compound may be used as it is as a part of a solvent for the polyurethane A, or may be removed by distillation or the like.

The monohydroxyl compound is introduced into the polyurethane A for the purpose of inhibiting increase of the molecular weight of the polyurethane A (that is, purpose of terminating the reaction), and in order to introduce the monohydroxyl compound into the polyurethane, the monohydroxyl compound is usually dropwise added to the reaction solution at 20 to 150° C., more preferably 70 to 140° C. Thereafter, the system is maintained at the same temperature to complete the reaction.

When the end group of the polyurethane molecule is a hydroxyl group, the monoisocyanate compound can be introduced into the polyurethane A. In order to introduce the monoisocyanate compound into the polyurethane A, the synthesis raw materials need to be used in the synthesis of the polyurethane A so that the number of isocyanate groups in the diisocyanate compound may become smaller than the total number of all the hydroxyl groups in the (poly)carbonate polyol, the carboxyl group-containing diol and the polyol in order that the end group of the polyurethane molecule may become a hydroxyl group.

When the reaction between all the hydroxyl groups in the (poly)carbonate polyol, the carboxyl group-containing diol and the polyol and the isocyanate groups in the diisocyanate compound is almost completed, the monoisocyanate compound is usually dropwise added to the reaction solution of polyurethane at 20 to 150° C., more preferably 70 to 140° C., in order to react the hydroxyl group remaining at the end of polyurethane with the monoisocyanate compound. By virtue of this, the monoisocyanate compound is introduced into the polyurethane A, and thereafter, the system is maintained at the same temperature to complete the reaction.

(Properties of Polyurethane (a))

The number-average molecular weight of polyurethane (a) for use in the present invention, such as the polyurethane A obtained as above, is preferably in the range of 1,000 to 100,000, more preferably 3,000 to 50,000, particularly preferably 5,000 to 30,000.

In the present specification, the “number-average molecular weight” is a number-average molecular weight in terms of polystyrene as measured by gel permeation chromatography (abbreviated to GPC hereinafter). When the number-average molecular weight is in the above range, a cured film obtained by thermally curing the thermosetting composition of the present invention (I) has sufficient elongation, flexibility and strength, further the solubility of the polyurethane (a) in the reaction solvent is satisfactory, and the viscosity of the thermosetting composition is in such a range as brings about no limitation on the use of the composition.

In the present invention, the measuring conditions of GPC are as follows, unless otherwise noted.

Apparatus name: HPLC Unit HSS-2000 manufactured by JASCO Corporation

Column: Shodex Column LF-804 (there columns connected)

Mobile phase: tetrahydrofuran

Flow rate: 1.0 mL/min

Detector: RI-2031Plus manufactured by JASCO Corporation

Temperature: 40.0° C.

Sample quantity: Sample loop 100μ liters

Sample concentration: adjusted to about 0.1% by mass.

From the viewpoint of a balance of properties of a cured product obtained by curing the thermosetting composition of the present invention (I), such as long-term insulation properties, low warpage properties and tensile elastic modulus, the acid value of the polyurethane (a) is preferably in the range of 5 to 120 mgKOH/g, more preferably 10 to 50 mgKOH/g. When the acid value is in the above range, the reactivity of the polyurethane (a) to other components contained in the thermosetting composition, such as the later-described compound (c), is not lowered, and regarding the cured product of the thermosetting setting composition of the present invention (I), sufficient heat resistance is attained.

It is preferable that the polyurethane (a) has a number-average molecular weight of 1,000 to 100,000 and an acid value of 5 to 120 mgKOH/g, and it is more preferable that the polyurethane (a) has a number-average molecular weight of 3,000 to 50,000 and an acid value of 10 to 50 mgKOH/g.

In the present specification, the acid value of the polyurethane (a) is an acid value as measured by the potent iometric titration method of JIS K0070.

(Solvent)

The polyurethane (a) is solid when it is alone, and therefore, by dissolving it in a solvent, it is easily homogeneously mixed with the later-described inorganic fine particles and/or organic fine particles (b) and compound (c), and handling thereof becomes easy. Accordingly, it is preferable to dissolve the polyurethane (a) in a solvent.

The polyurethane (a) is synthesized usually in a reaction solvent as previously described, and therefore, it is usually present in a dissolved state in a reaction solvent at the time when it is synthesized. This reaction solvent can be used as it is as the aforesaid solvent. When the viscosity of the solution in which the polyurethane (A) has been dissolved in the solvent is high, an additional solvent may be added.

Examples of the solvents used herein include γ-butyrolactone, diethylene glycol diethyl ether, diethylene glycol monoethyl ether acetate, diethylene glycol butyl methyl ether, tripropylene glycol dimethyl ether, triethylene glycol dimethyl ether, diethylene glycol monobutyl ether, butyl.phenyl ether, amyl phenyl ether, diethylene glycol monoisopropyl ether, diethylene glycol monoisobutyl ether and dipropylene glycol monopropyl ether.

The above solvents may be used singly or may be used in combination of two or more kinds.

<Inorganic Fine Particles and/or Organic Fine Particles>

Next, the inorganic fine particles and/ororganic fine particles (b) are described.

By adding the inorganic fine particles and/or organic fine particles (b) to the thermosetting composition, heat resistance can be imparted to a cured product obtained by curing the composition.

In the present invention, the “inorganic fine particles and/or organic fine particles” are defined to include not only inorganic fine particles and organic fine particles but also organic/inorganic composite type fine particles wherein a powdery inorganic compound has been physically coated or chemically surface-treated with an organic compound.

The inorganic fine particles for use in the present invention (I) are not specifically restricted provided that they can be dispersed in the thermosetting composition of the present invention (I) to form a paste.

Examples of such inorganic fine particles include silica (SiO₂) alumina (Al₂O₃) titania (TiO₂), tantalum oxide (Ta₂O₅) zirconia (ZrO₂), silicon nitride (Si₃N₄), barium titanate (BaO—TiO₂), barium carbonate (BaCO₃), lead titanate (PbO—TiO₂) lead zirconate titanate (PZT), zirconate titanate lead lanthanum (PLZT), galliumoxide (Ga₂O₃), spinel (MgO.Al₂O₃), mullite (3Al₂O₃.2SiO₂) cordierite (2MgO.2Al₂O₃.5SiO₂) talc (3MgO.4SiO₂.H₂O), aluminum titanate (TiO₂—Al₂O₃) yttria-containing zirconia (Y₂O₃—ZrO₂), barium silicate (BaO.8SiO₂), boronnitride (BN), calciumcarbonate (CaCO₃), calciumsulfate (CaSO₄) zinc oxide (ZnO), magnesiumtitanate (MgO.TiO₂) barium sulfate (BaSO₄), organic bentonite, and carbon (C).

Of these, from the viewpoints of the balance of electrical insulation properties and heat resistance of a cured product obtained from the thermosetting composition, silica is preferable.

The organic fine particles for use in the present invention (I) are not particularly restricted provided that they are dispersed in the thermosetting composition of the present invention (I) to form a paste.

As such organic fine particles, fine particles of a heat-resistant resin having an amide bond, an imide bond, an ester linkage or an ether linkage are preferable. As such resins, a polyimide resin or its precursor, a polyamidoimide resin or its precursor, and a polyamide resin are preferably mentioned from the viewpoints of heat resistance and mechanical properties.

The mean particle diameter of the inorganic fine particles and/or organic fine particles (b) is preferably in the range of 0.01 to 10 μm, more preferably 0.1 to 5 μm.

The amount of the inorganic fine particles and/or organic fine particles (b) described above may be used singly, or two or more kinds may be used in combination. The amount thereof blended in the thermosetting composition of the present invention (I) is usually in the range of 1 to 150 parts by mass, preferably 1 to 120 parts by mass, more preferably 1 to 60 parts by mass, based on 100 parts by mass of the components (a) contained in the thermosetting resin composition.

<Compound (c) Having Two or More Epoxy Groups in One Molecule>

Next, the compound (c) is described.

The compound (c) is not specifically restricted provided that it is a compound other than the polyurethane (a) and is a compound having two or more epoxy groups in one molecule. Although the number of epoxy groups in the compound (c) is usually not more than 25, it is preferably 2 to 4. The compound (c) functions as a curing agent in the thermosetting composition of the present invention (I).

Examples of the Compound (c) include:

novolak type epoxy resins obtained by epoxidizing novalak resins that are obtained by condensing or cocondensing phenol, cresol, xylenol, resorcinol, catechol, phenols and/or naphthols (such as α-naphthol, β-naphthol or dihydroxynaphthalene) with compounds having an aldehyde group, such as formaldehyde, acetaldehyde, propionaldehyde, benzaldehyde or salycylaldehyde, in the presence of an acidic catalyst, e.g., phenolic novolak type epoxy resin and orthocresol novolak type epoxy resin;

diglycidyl ethers of bisphenol A, bisphenol F, bisphenol S, alkyl substituted or unsubstituted biphenol, stilbene-based phenols or the like (bisphenol A type epoxy compound, bisphenol F type epoxy compound, bisphenol S type epoxy compound, biphenyl type epoxy compound, stilbene type epoxy compound); glycidyl ethers of alcohols such as butanediol, polyethylene glycol and polypropylene glycol;

glycidyl ester type epoxy resins of carboxylic acids such as phthalic acid, isophthalic acid and tetrahydrophthalic acid;

glycidyl type or methylglycidyl type epoxy resins, such as compounds wherein an active hydrogen bonded to a nitrogen atom of aniline, bis(4-aminophenyl)methane, isocyanuric acid or the like is replaced with glycidyl group;

glycidyl type or methylglycidyl type epoxy resins, such as compounds wherein an active hydrogen bonded to a nitrogen atom and an active hydrogen of a phenolic hydroxyl group of aminophenols such as p-aminophenol are replaced with glycidyl groups;

alicyclic epoxy resins, such as vinylcyclohexene diepoxide, 3,4-epoxycyclohexylmethyl-3,4-epoxycyclohexane carboxylate, and 2-(3,4-epoxy)cyclohexyl-5,5-spiro(3,4-epoxy)cyclohexane-m-dioxane obtained by epoxydizing olefin bond in a molecule;

glycidyl ethers of para-xylylene and/or meta-xylylene modified phenolic resins;

glycidyl ethers of terpene modified phenolic resins;

glycidyl ethers of dicyclopentadiene modified phenolic resins;

glycidyl ethers of cyclopentadiene modified phenolic resins;

glycidyl ethers of polycyclic aromatic ring modified phenolic resins;

glycidyl ethers of naphthalene ring-containing phenolic resins;

halogenated phenol novolak type epoxy resins;

hydroquinone type epoxy resins;

trimethylolpropane type epoxy resins;

linear aliphatic epoxy resins obtained by oxidizing an olefin bond with a peracid such as peracetic acid;

diphenylmethane type epoxy resins;

epoxidation products of aralkyl type phenolic resins such as phenol aralkyl resin and naphthol aralkyl resin;

sulfur atom-containing epoxy resins;

diglycidyl ether of tricyclo[5,2,1,0^{2,6}]decane dimethanol; and

epoxy resins having adamantane structure, such as 1,3-bis(1-adamantyl)-4,6-bis(glycidyloyl)benzene, 1-[2′,4′-bis(glycidyloyl)phenyl]adamantane, 1,3-bis(4′-glycidyloylphenyl)adamantane and 1,3-bis[2′,4′-bis(glycidyloyl)phenyl]adamantane.

Of these, a compound having an aromatic ring structure and/or an alicycic structure is preferable as the compound (c), from the viewpoints of high elastic modulus, heat resistance and electrical insulation properties of a cured product obtained from the thermosetting composition of the present invention (I).

When long-term electrical insulation performance of the later-described cured product of the present invention (II) is considered to be important, compounds having a tricyclodecane structure and an aromatic ring structure, for example, glycidyl ether of dicyclopentadiene-modified phenol resin (that is, compound having a tricycle[5,2,1,0^{2,6}] decane structure and an aromatic ring structure), and epoxy resins having an adamantane structure (that is, compounds having a tricycle[3,3,1,1^{3,7}]decane structure and an aromatic ring structure), such as 1,3-bis(1-admantyl)-4,6-bis(glycidyloyl)benzene, 1-[2′,4′-bis(glycidyloyl)phenyl]adamantane, 1,3-bis(4′-glycidyloylphenyl)adamantane and 1,3-bis[2′,4′-bis(glycidyloyl)phenyl]adamantine, are preferable among the compounds having an aromatic ring structure and/or an alicyclic structure, because they can provide cured products of low water absorption ratio. Particularly preferable is a compound of the following formula (2).

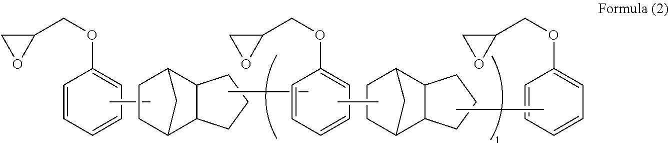

(wherein l is an integer of not less than 0 but not more than 20.)

On the other hand, when reactivity to the polyurethane (a) is considered to be important, compounds having an amino group and an aromatic ring structure, for example, aniline, glycidyl type or methylglycidyl type epoxy resins, such as resins wherein active hydrogen bonded to a nitrogen atom of bis(4-aminophenyl)methane is replaced with a glycidyl group, and glycidyl type or methylglycidyl type epoxy resins, such as resins wherein active hydrogen bonded to a nitrogen atom and active hydrogen of a phenolic hydroxyl group of aminophenols, such as p-aminophenol, is replaced with a glycidyl group, are preferable among the compounds having an aromatic ring structure and/or an alicyclic structure. Particularly preferable is a compound of the following formula (3).

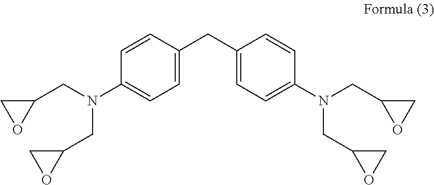

The compounds (c) described above may be used singly or may be used in combination of two or more kinds.

The amount of the compound (c) added based on 100 parts by mass of the polyurethane (a) cannot be said unconditionally because it varies depending upon the acid value of the polyurethane (a).

However, the ratio of the number of functional groups having reactivity to epoxy groups contained in the polyurethane (a) to the number of epoxy groups in the compound (c) having two or more epoxy groups in one molecule (functional groups having reactivity to epoxy groups/epoxy groups) is preferably in the range of 1/3 to 2/1, more preferably 1/2.5 to 1.5/1. When the ratio is in the above range, the possibility of a large amount of unreacted polyurethane (a) or an unreacted compound (c) remaining is low, and therefore, too many functional groups having reactivity to unreacted epoxy groups do not remain. Hence, regarding a cured product of the thermosetting composition of the present invention (I), satisfactory electrical insulation performance is achieved.

<Tensile Elastic Modulus of Cured Product Obtained from Thermosetting Composition Containing Components (a) to (c)>

The tensile elastic modulus of a cured product obtained by curing the thermosetting composition containing the components (a) to (c) described above is also in the range of 0.5 to 2.0 GPa. In order to realize a tensile elastic modulus of this range, types and proportions of the components (a) to (c) have to be only controlled, and for example, the amount of the component (b) is controlled so that the tensile elastic modulus may be in the above range. When the amount of the component (b) is increased, the tensile elastic modulus is raised. In order to raise the tensile elastic modulus, a component having high Tg or a high softening point may be used as the component (c). For example, if a compound having an aromatic ring structure and/or an alicyclic structure (such a compound has high Tg) is used as the component (c), the tensile elastic modulus can be raised. When the amount of such a compound having high Tg or a high softening point is increased, the tensile elastic modulus can be raised. In order that a cured product obtained by curing the thermosetting composition of the present invention may easily attain a tensile elastic modulus of 0.5 to 2.0 GPa, it is preferable to use a compound containing 3 to 5 epoxy groups inonemolecule as the component (c), and it is more preferable to use a compound that is solid at ordinary temperature.

[Other Components]

(Curing Accelerator)

When the thermosetting composition of the present invention (I) contains the polyurethane (a) and the compound (c), a curing accelerator is preferably used in combination. The curing accelerator is not specifically restricted provided that it is a compound which accelerates reaction between an epoxy group in the compound (c) and a functional group in the polyurethane (a), said functional group having reactivity to the epoxy group.

Examples of the curing accelerators include triazine-based compounds such as melamine, acetoguanamine, benzoguanamine, 2,4-diamino-6-methacryloyloxyethyl-5-triazine, 2,4-methacryloyloxyethyl-s-triazine, 2,4-diamino-6-vinyl-s-triazine and 2,4-diamino-6-vinyl-s-triazine.isocyanuric acid adduct; imidazole-based compounds, such as imidazole, 2-methylimidazole, 2-ethyl-4-methylimidazole, 2-phenylimidazole, 2-undecylimidazole, 2-heptadecylimidazole, 1-benzyl-2-methylimidazole, 2-phenyl-4-methylimidazole, 1-cyanoethyl-2-methylimidazole, 1-cyanoethyl-2-ethyl-4-methylimidazole, 1-aminoethyl-2-ethyl-4-methylimidazole, 1-aminoethyl-2-methylimidazole, 1-(cyanoethylaminoethyl)-2-methylimidazole, N-[2-(2-methyl-1-imidazolyl)ethyl]urea, 1-cyanoethyl-2-undecylimidazole, 1-cyanoethyl-2-methylimidazolium trimellitate, 1-cyanoethyl-2-phenylimidazolium trimellitate, 1-cyanoethyl-2-ethyl-4-methylimidazolium trimellitate, 1-cyanoethyl-2-undecylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 1-dodecyl-2-methyl-3-benzylimidazolium chloride, N,W-bis(2-methyl-1-imidazolylethyl)urea, N,N′-bis(2-methyl-1-imidazolylethyl)adipoamide, 2-phenyl-4-methyl-5-hydroxymethylimidazole, 2-phenyl-4,5-dihydroxymethylimidazole, 2-methylimidazole.isocyanuric acid adduct, 2-phenylimidazole.isocyanuric acid adduct, 2,4-diamino-6-[2′-methylimidazolyl-(1′)]-ethyl-s-triazine-isocya nuric acid adduct, 2-methyl-4-formylimidazole, 2-ethyl-4-methyl-5-formylimidazole, 2-phenyl-4-methylformylmidazole, 1-benzyl-2-phenylimidazole, 1,2-dimethylimidazole, 1-(2-hydroxyethyl)imidazole, vinylimidazole, 1-methylimidazole, 1-allylimidazole, 2-ethylimidazole, 2-butylimidazole, 2-butyl-5-hydroxymethylimidazole, 2,3-dihydro-1H-pyrrolo[1,2-a]benzimidazole, 1-benzyl-2-phenylimidazole hydrobromide and 1-dodecyl-2-methyl-3-benzylimidazolium chloride; cycloamidine compounds and derivatives thereof, e.g., diazabicycloalkenes such as 1,5-diazabicyclo(4.3.0)nonene-5 and its salt and 1,8-diazabicyclo(5.4.0)undecene-7 and its salt; tertiary amino group-containing compounds such as triethylenediamine, benzyldimethylamine, triethanolamine, dimethylaminoethanol and tris(dimethylaminomethyl)phenol; organic phosphine compounds such as triphenylphosphine, diphenyl(p-tolyl)phosphine, tris(alkylphenyl)phosphine, tris(alkoxyphenyl)phosphine, tris(alkyl.alkoxyphenyl)phosphine, tris(dialkylphenyl)phosphine, tris(trialkylphenyl)phosphine, tris(tetraalkylphenyl)phosphine, tris(dialkoxyphenyl)phosphine, tris(trialkoxyphenyl)phosphine, tris(tetraalkoxyphenyl)phosphine, trialkylphosphine, dialkylarylphosphine and alkyldiarylphosphine; and dicyan diazide.

These curing accelerators may be used singly or may be used in combination of two or more kinds.

When compatibility of the curing acceleration action with the electrical insulation performance of the later-described cured product of the present invention (II) is taken into account, preferred curing accelerators among these curing accelerators are melamine, an imidazole compound, a cycloamidine compound and its derivatives, a phosphine-based compound and an amine-based compound, and more preferred are melamine, 1,5-diazabicyclo(4.3.0)nonene-5 and its salts, and 1,8-diazabicyclo(5.4.0)undecene-7 and its salts.

The amount of the curing accelerator added is not specifically restricted provided that the curing acceleration effect can be achieved. However, from the viewpoints of curability of the thermosetting composition of the present invention (I) and electrical insulation properties and moisture resistance of a cured product obtained by curing the thermosetting composition of the present invention (I), the curing accelerator is preferably added in an amount of 0.05 to 5 parts by mass, more preferably 0.1 to 3.0 parts by mass, based on 100 parts by mass of the total amount of the polyurethane (a) and the compound (c). When the curing accelerator is added in the above amount, the thermosetting composition of the present invention (I) can be cured in a short period of time, and the resulting cured product has satisfactory electrical insulation properties and moisture resistance.

(Defoaming Agent)

From the thermosetting composition of the present invention

(I), a cured product having excellent electrical insulation properties is obtained, and therefore, the composition is employable as a composition for insulating protective films such as a resist.

When the thermosetting composition of the present invention (I) is used as a composition for a resist (i.e., resist ink composition), a defoaming agent can be added to the composition for the purpose of eliminating or suppressing occurrence of bubbles during printing, and addition thereof is preferable.

The defoaming agent is not specifically restricted provided that it literally has a function of eliminating or suppressing air bubbles occurring when a resist ink composition is printed.

Specific examples of the defoaming agents used for the thermosetting composition of the present invention (I) include silicone-based defoaming agents such as BYK-077 (available from BYK Japan K.K.), SN Defoamer 470 (available from San Nopco Limited), TSA750S (available from Momentive Performance Materials Inc.) and Silicone Oil SH-203 (available from Dow Corning Toray Co., Ltd.); acrylic polymer-based defoaming agents such as Dappo SN-348 (available from San Nopco Limited), Dappo SN-354 (available from San Nopco Limited), Dappo SN-368 (available from San Nopco Limited) and Disparlon 230HF (available from Kusumoto Chemicals, Ltd.); acetylene diol-based defoaming agents such as Surfinol DF-110D (available from Nisshin Chemical Industry Co., Ltd.) and Surfinol DF-37 (available from Nisshin Chemical Industry Co., Ltd.); and fluorine-containing silicone-based defoaming agents such as FA-630.

(Others)

To the thermosetting composition of the present invention (I), surface active agents such as leveling agent, and publicly known colorants such as Phthalocyanine Blue, Phthalocyanine Green, Iodine Green, Disazo Yellow, Crystal Violet, Carbon Black and Naphthalene Black, can be further added, when needed.

When it is necessary to inhibit oxidation deterioration of the polyurethane (a) and discoloration during heating, antioxidants, such as a phenol-based antioxidant, a phosphite-based antioxidant and a thioether-based antioxidant, can be added to the thermosetting composition of the present invention (I), and addition thereof is preferable.

Examples of the phenol-based antioxidants include compounds represented by the following formulas (4) to (14).

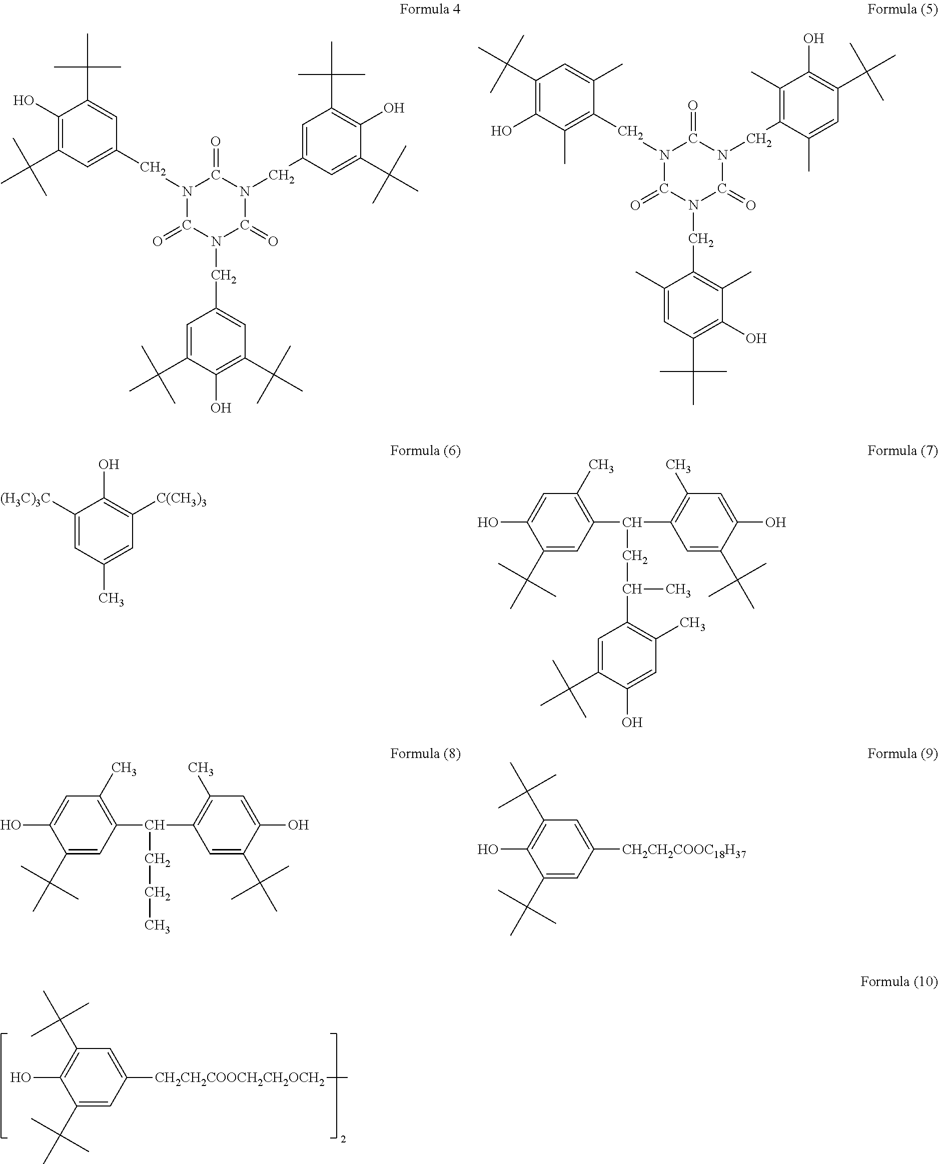

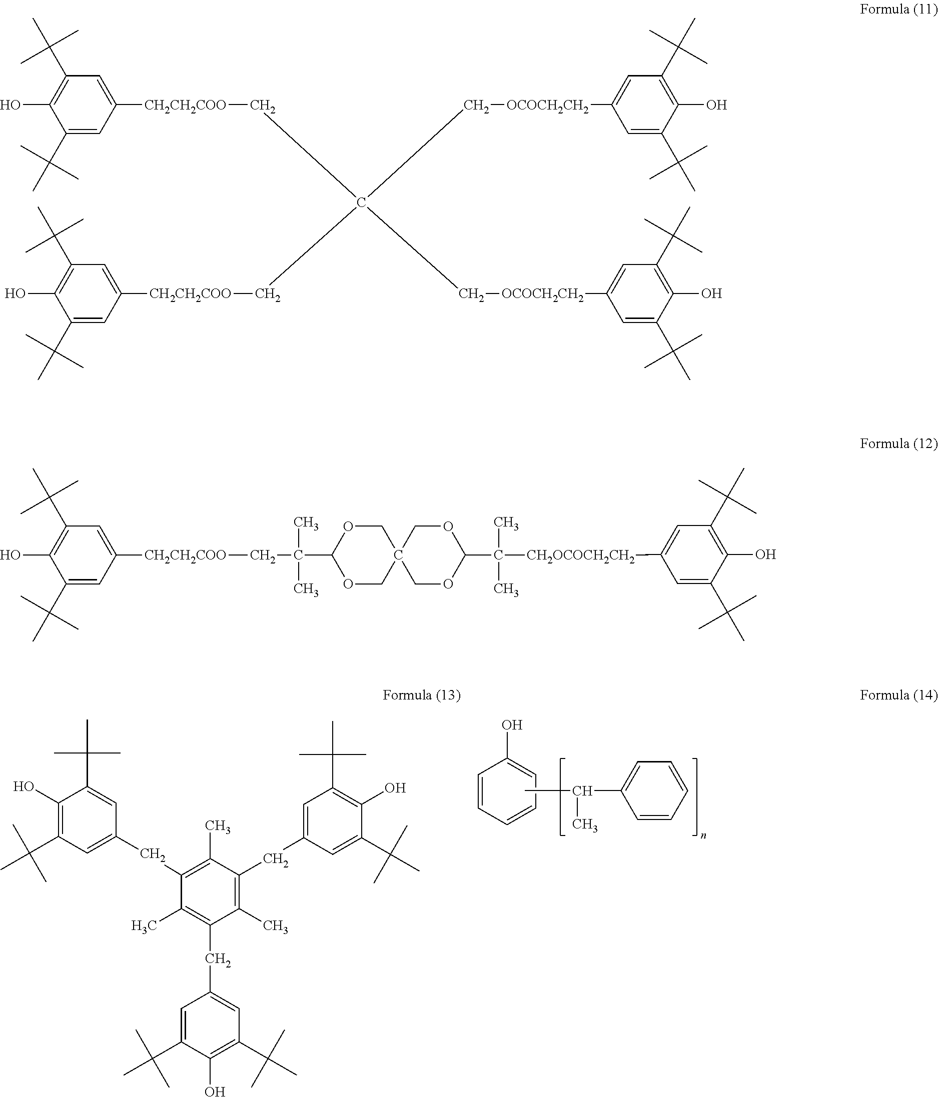

(In the formula (14), n is an integer of 1 to 5.)

Examples of the phosphite-based antioxidants include compounds represented by the following formulas (15) to (25)

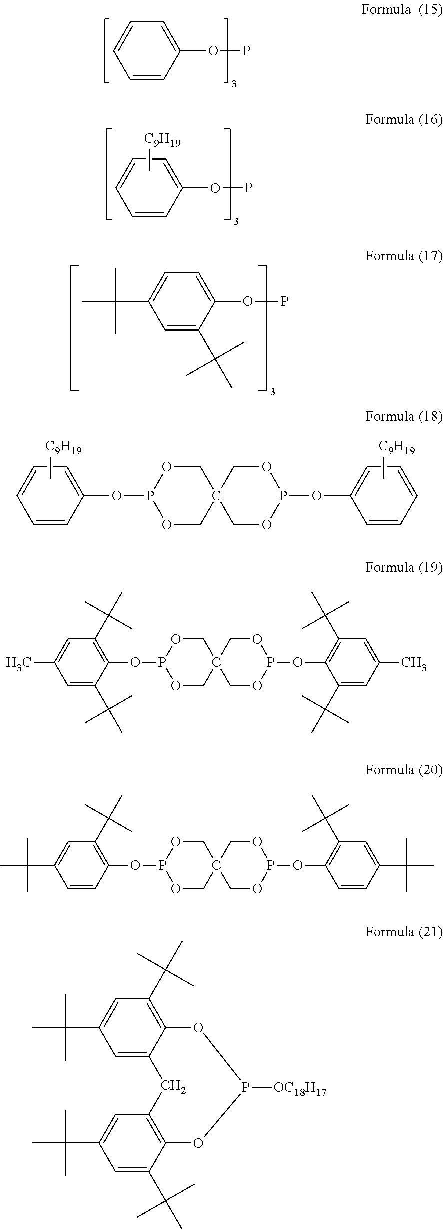

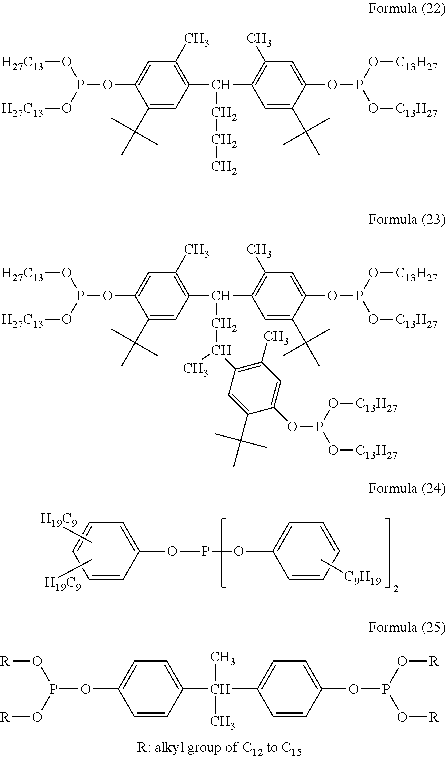

Examples of the thioether-based antioxidants include compounds represented by the following formulas (26) to (31).

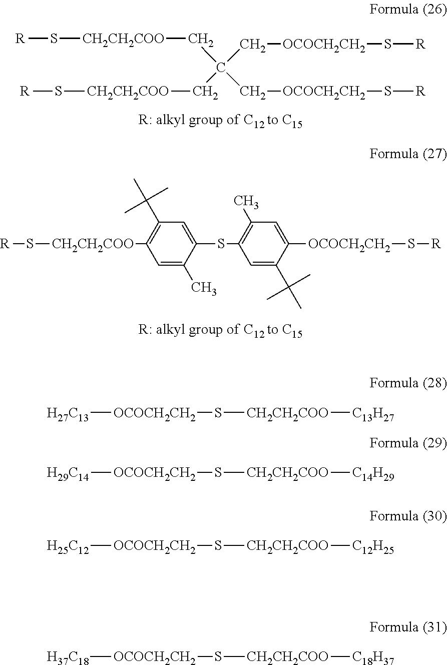

To the thermosetting composition of the present invention (I), a flame retardant and a lubricant can be also added, when needed.

<Process for Preparing Thermosetting Composition>

The thermosetting composition of the present invention (I) can be obtained by, for example, homogenously kneading and mixing all the blending components by a roll mill, a bead mill or the like.

When the thermosetting composition contains the components (a) to (c), the thermosetting composition of the present invention (I) can be obtained also by the following process in order to prevent thermal curing of the polyurethane (a) and the compound (c) caused by generation of heat due to shearing in the kneading and mixing process.

That is to say, the components except the compound (c) are mixed to obtain a main agent blend. As previously described, the polyurethane (a) is synthesized using a solvent and is usually used in a dissolved state in a solvent, and therefore, in the main agent blend, the components except the compound (c) have been dissolved or dispersed in the solvent.

The compound (c) has high viscosity and is hard to handle when it is alone, so that the compound (c) is dissolved in a solvent to obtain a curing agent solution. By mixing this curing agent solution with the main agent blend, the thermosetting composition of the present invention (I) is obtained. The solvent employable for dissolving the compound (c) is the same as the aforesaid solvent employable for dissolving the polyurethane (a).

<Thixotropy Index of Thermosetting Composition>

The thixotropy index of the thermosetting composition of the present invention (I) is not specifically restricted, but from the viewpoints of printability and prevention of sedimentation of the component (b), it is preferably not less than 1.1. The thixotropy index is usually not more than 2.0.

### [Present Invention (II)]

Next, the cured product of the present invention (II) is described.

The cured product of the present invention (II) is generally obtained by removing a part or all of the amount of the solvent contained in the thermosetting composition of the present invention (I) (this step is unnecessary when the thermosetting composition of the present invention (I) does not contain a solvent) and then promoting the curing reaction by heating. For example, when the cured product of the present invention (II) is obtained as a cured film, the cured film can be obtained through the following first to third steps.

First Step

A step of printing the thermosetting composition of the present invention (I) (especially when the composition contains the components (a) to (c), the composition usually contains a reaction solvent necessary for the synthesis of the polyurethane (a)) on a substrate or the like to obtain a coating film.

Second Step

A step of placing the coating film obtained in the first step in an atmosphere of 50° C. to 100° C. to evaporate the solvent from the coating film, whereby a coating film from which a part or all of the amount of the solvent has been removed is obtained.

Third Step

A step of thermally curing the coating film obtained in the second step in an atmosphere of 100° C. to 250° C. to obtain a cured film.

The first step is a step wherein the thermosetting composition of the present invention (I) is printed on a substrate or the like to obtain a coating film. The printing method is not particularly restricted. A coating film can be obtained by coating the thermosetting composition onto a substrate or the like by, for example, screen printing method, roll coater method, spraying method or curtain coater method.

The second step is a step wherein the coating film obtained in the first step is placed in an atmosphere of 50° C. to 100° C. to evaporate the solvent from the coating film, whereby a coating film from which a part or all of the amount of the solvent has been removed is obtained. The time for removing the solvent is preferably not longer than 4 hours, more preferably not longer than 2 hours. As described above, this step is unnecessary when the thermosetting composition of the present invention (I) does not contain a solvent.

The third step is a step wherein the coating film obtained in the second step is thermally cured in an atmosphere of 100° C. to 250° C. to obtain a cured film. The time for thermal curing is preferably in the range of 20 minutes to 4 hours, more preferably 30 minutes to 2 hours.

Since the cured product of the present invention (II) produced through, for example, such steps as above and having a tensile elastic modulus of the above specific range is excellent in ability to protect wiring and exerts no negative influence on the flexibility and the low warpage properties of a flexible wiring board, it is useful as a wiring protective film such as a solder resist. Moreover, as is apparent from the later-described working examples, the cured product is excellent also in electrical insulation properties, and hence, the cured product can be favorably used for general insulating films

[Present Invention (III)]

Next, the present invention (III) is described.

The present invention (III) is a process for producing a flexible wiring board having an insulating film, which is characterized by having the steps of applying the curable composition described in the present invention (I) onto a wiring pattern of a flexible wiring board comprising the wiring pattern formed on a flexible substrate, by a printing method to form a printed film on the pattern, and heating the printed film at 80 to 130° C. to cure the film and to thereby form an insulating film from the printed film.

When the line width of the flexible wiring board is not more than 20 μm (line width is usually not less than 3 μm), the effects of the present invention are remarkably exerted, as previously described. The wiring pattern of the flexible wiring board has been usually subjected to tin plating.

The thermosetting composition of the present invention (I) can be used as, for example, a solder resist ink, as previously described, and the cured product of the present invention (II) can be used as an insulating protective film of wiring. In particular, the cured product can be favorably used as a solder resist that is used for covering at least a part of wiring of a flexible wiring board such as a chip-on-film.

Hereinafter, specific steps conducted in the process for producing a flexible wiring board having a protective film of the present invention (III) are described. The flexible wiring board having an insulating film can be produced through, for example, the following steps A to C.

Step A

A step wherein the thermosetting composition of the present invention (I) is printed on a wiring pattern of a flexible wiring board by screen printing or the like to obtain a printed film.

Step B

A step wherein the printed film obtained in the step A is placed in an atmosphere of 40 to 100° C. to evaporate the solvent from the printed film, whereby a printed film from which a part or the whole of the solvent has been removed is obtained.

Step C

A step wherein the printed film obtained in the step B is thermally cured in an atmosphere of 80 to 130° C. to form a protective film of a flexible wiring board from the printed film.

When the evaporation rate of the solvent and the smooth shift to the next step (step C) are taken into account, the temperature for evaporating the solvent in the step B is in the range of 40 to 100° C., preferably 60 to 100° C., more preferably 70 to 90° C. The time for the evaporation of the solvent in the step B is not specifically restricted, but it is preferably in the range of 10 to 120 minutes, more preferably 20 to 100 minutes. When the thermosetting composition of the present invention (I) does not contain a solvent, this step is unnecessary.

From the viewpoint that low warpage properties and flexibility preferable for an insulating protective film are obtained and from the viewpoint that diffusion of a tin-plating layer is prevented in the case where the wiring pattern has been subjected to tin plating, the heating temperature of the thermal curing conditions in the step C is in the range of 80 to 130° C. The heating temperature is preferably 90 to 130° C., more preferably 110 to 130° C. The thermal curing time in the step C is not specifically restricted, but it is preferably 20 to 150 minutes, more preferably 30 to 120 minutes.

Through such steps as above, a flexible wiring board having an insulating film, wherein a wiring pattern-side surface of a flexible wiring board comprising a wiring pattern formed on a flexible substrate is at least partially covered with an insulating film (cured product of the present invention (II)), is obtained.

### EXAMPLES

The present invention is further described with reference to the following examples, but it should be construed that the present invention is in no way limited to those examples only.

<Measurement of Acid Value of Polyurethane (a)>

The solvents in the polyurethane solution obtained in the following Synthesis Examples were distilled away under reduced pressure by heating to obtain a polyurethane (a).

Using the polyurethane (a) obtained by the above method, an acid value was measured in accordance with the potentiometric titration method of JIS K0070.

The apparatus used in the potentiometric titration method is described below.

Apparatus name: automatic potentiometric titration apparatus AT-510 manufactured by Kyoto Electronics Manufacturing Co., Ltd.

Electrode: composite glass electrode C-173 manufactured by Kyoto Electronics Manufacturing Co., Ltd.

<Measurement of Number-Average Molecular Weight of Polyurethane (a)>

The number-average molecular weight is a number-average molecular weight in terms of polystyrene as measured by GPC, and the measuring conditions of GPC adopted in Examples are as follows.

Apparatus name: HPLC Unit HSS-2000 manufactured by JASCO Corporation

Column: Shodex Column LF-804 (three columns connected)

Mobile phase: tetrahydrofuran

Flow rate: 1.0 mL/min

Detector: RI-2031Plus manufactured by JASCO Corporation

Temperature: 40.0° C.

Sample quantity: Sample loop 100μ liters

Sample concentration: adjusted to about 0.1% by mass

### <Synthesis of Polyurethane (a) Having Carboxyl Group and Carbonate Bond>

### Synthesis Example 1

A reaction container equipped with a stirring device, a thermometer and a condenser was charged with 248.0 g of C-1015N (polycarbonate diol available from Kuraray Co., Ltd.; raw material diols: 1,9-nonanediol and 2-methyl-1,8-octanediol in a charging molar ratio of 15:85 (1,9-nonanediol:2-methyl-1,8-octanediol), hydroxyl value: 112.3 mgKOH/g, residual concentration of 1,9-nonanediol: 2.1% by mass, residual concentration of 2-methyl-1,8-octanediol: 9.3% by mass) as a (poly)carbonate polyol, 47.5 g of 2,2-dimethylolbutanoic acid (available from Nippon Kasei Chemical Co., Ltd.) as a carboxyl group-containing diol, 2.7 g of trimethylolethane (available from Mitsubishi Chemical Corporation) as a polyol other than the (poly)carbonate polyol and the carboxyl group-containing diol, and 467.5 g of γ-butyrolactone (available from Mitsubishi Chemical Corporation) and 82.5 g of diethylene glycol diethyl ether (available from Nippon Nyukazai Co., Ltd.) as solvents, and they were heated to 100° C. to dissolve all the raw materials.

The temperature of the reaction solution was lowered down to 90° C., and by the use of a dropping funnel, 150.4 g of methylenebis(4-cyclohexyl isocyanate) (available from Sumika Bayer Urethane Co., Ltd., trade name: Desmodur-W) was dropwise added as a diisocyanate compound over a period of 30 minutes.

The reaction was carried out at 120° C. for 8 hours, and it was confirmed by the infrared absorption spectrum analysis that the diisocyanate compound had been almost consumed. Thereafter, 1.5 g of ethanol (available from Wako Pure Chemical Industries, Ltd.) was dropwise added to the reaction solution, and the reaction was further carried out at 80° C. for 3 hours to obtain a polyurethane solution having a carboxyl group and a carbonate bond (referred to as a “polyurethane solution A1” hereinafter).

The number-average molecular weight of polyurethane having a carboxyl group and a carbonate bond (referred to as “polyurethane AU1” hereinafter) contained in the resulting polyurethane solution A1 was 14,000, and the acid value of the polyurethane AU1 was 40.0 mg-KOH/g. The solids concentration of the polyurethane solution A1 was 45.0% by mass.

### Synthesis Example 2

A reaction container equipped with a stirring device, a thermometer and a condenser was charged with 252.8 g of C-1015N (polycarbonate diol available from Kuraray Co., Ltd.; raw material diols: 1,9-nonanediol and 2-methyl-1,8-octanediol in a charging molar ratio of 15:85 (1,9-nonanediol:2-methyl-1,8-octanediol), hydroxyl value: 112.3 mgKOH/g, residual concentration of 1,9-nonanediol: 7.5% by mass, residual concentration of 2-methyl-1,8-octanediol: 4.4% by mass) as a (poly)carbonate polyol, 47.5 g of 2,2-dimethylolbutanoic acid (available from Nippon Kasei Chemical Co., Ltd.) as a carboxyl group-containing diol, and 467.5 g of γ-butyrolactone (available from Mitsubishi Chemical Corporation) and 82.5 g of diethylene glycol diethyl ether (available from Nippon Nyukazai Co., Ltd.) as solvents, and they were heated to 100° C. to dissolve all the raw materials.

The temperature of the reaction solution was lowered down to 90° C., and by the use of a dropping funnel, 145.6 g of methylenebis(4-cyclohexyl isocyanate) (available from Sumika Bayer Urethane Co., Ltd., trade name: Desmodur-W) was dropwise added as a diisocyanate compound over a period of 30 minutes.

The reaction was carried out at 120° C. for 8 hours, and it was confirmed by the infrared absorption spectrum analysis that the diisocyanate compound had been almost consumed. Thereafter, 4.0 g of isobutanol (available from Wako Pure Chemical Industries, Ltd.) was dropwise added to the reaction solution, and the reaction was further carried out at 80° C. for 3 hours to obtain apolyurethane solution having a carboxyl group and a carbonate bond (referred to as a “polyurethane solution A2” hereinafter).

The number-average molecular weight of polyurethane having a carboxyl group and a carbonate bond (referred to as “polyurethane AU2” hereinafter) contained in the resulting polyurethane solution A2 was 13,000, and the acid value of the polyurethane AU2 was 40.0 mg-KOH/g. The solids concentration of the polyurethane solution A2 was 45.0% by mass.

<Preparation of Main Agent Blend>

### Blending Example 1

111.1 g of the polyurethane solution A1, 5.0 g of a silica powder (available from Nippon Aerosil Co., Ltd., trade name: Aerosil R-974), 0.36 g of melamine (available from Nissan Chemical Industries, Ltd.) as a curing accelerator and 0.70 g of a defoaming agent (available from Momentive Performance Materials Inc., trade name: TSA750S) were mixed together.

Mixing of this polyurethane solution A1 with the silica powder, the curing accelerator and the defoaming agent was carried out by the use of a three-roll mill (manufactured by Inoue Manufacturing Co., Ltd., type: S-4_{3/4}×11). The resulting blend was taken as a main agent blend C1.

### Blending Example 2

A polyurethane solution, a silica powder, melamine and a defoaming agent were mixed in the same manner as in Blending Example 1, except that the polyurethane solution A1 was replaced with the polyurethane solution A2. The resulting blend was taken as a main agent blend C2.

<Preparation of Solution Containing Compound (c)>

To a container equipped with a stirring device, a thermometer and a condenser, 300 g of an epoxy resin represented by the following formula (2) (available from DIC Corporation, grade name: HP-7200H, epoxy equivalent: 278 g/eq, main component: resin having 3 epoxy groups per molecule, solid at ordinary temperature) and 300 g of γ-butyrolactone (available from Mitsubishi Chemical Corporation) were added, and stirring was started. With continuing stirring, the temperature in the container was raised to 70° C. by the use of an oil bath. After the internal temperature of the container was raised to 70° C., stirring was continued for 30 minutes. Thereafter, it was confirmed that HP-7200H had been completely dissolved, and then the solution was cooled down to room temperature to obtain a HP-7200H-containing solution having a concentration of 50% by mass. This solution is taken as a curing agent solution E1.

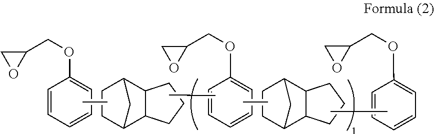

(In the above formula, l is an integer of not less than 0 but not more than 20.)

### Preparation Example 2

To a container equipped with a stirring device, a thermometer and a condenser, 300 g of an epoxy resin represented by the following formula (32) (available from DIC Corporation, grade name: HP-4700, epoxy equivalent: 165 g/eq, having 4 epoxy groups in one molecule, solid at ordinary temperature) and 300 g of γ-butyrolactone (available from Mitsubishi Chemical Corporation) were added, and stirring was started. With continuing stirring, the temperature in the container was raised to 70° C. by the use of an oil bath. After the internal temperature of the container was raised to 70° C., stirring was continued for 30 minutes. Thereafter, it was confirmed that HP-4700 had been completely dissolved, and then the solution was cooled down to room temperature to obtain a HP-4700-containing solution having a concentration of 50% by mass. This solution is taken as a curing agent solution E2.

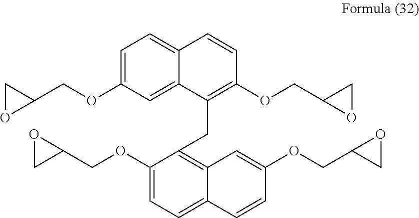

### Preparation Example 3

To a container equipped with a stirring device, a thermometer and a condenser, 300 g of an epoxy resin having a repeating structure unit represented by the following formula (33) (available from Nippon Kayaku Co., Ltd., grade name: NC-7000, epoxy equivalent: 230 g/eq, main component: resin having 8 epoxy groups per molecule, solid at ordinary temperature) and 300 g of γ-butyrolactone (available from Mitsubishi Chemical Corporation) were added, and stirring was started. With continuing stirring, the temperature in the container was raised to 70° C. by the use of an oil bath. After the internal temperature was raised to 70° C., stirring was continued for 30 minutes. Thereafter, it was confirmed that NC-7000 had been completely dissolved, and then the solution was cooled down to room temperature to obtain a NC-7000-containing solution having a concentration of 50% by mass. This solution is taken as a curing agent solution E3.

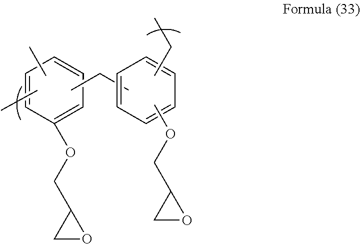

### Preparation Example 4

To a container equipped with a stirring device, a thermometer and a condenser, 300 g of an epoxy resin having a structure of bisphenol A type (available from Japan Epoxy Resins Co., Ltd., grade name: JER1004, epoxy equivalent: 925 g/eq, having 2 epoxy groups in one molecule, solid at ordinary temperature) and 300 g of γ-butyrolactone (available from Mitsubishi Chemical Corporation) were added, and stirring was started. With continuing stirring, the temperature in the container was raised to 70° C. by the use of an oil bath. After the internal temperature of the container was raised to 70° C., stirring was continued for 30 minutes. Thereafter, it was confirmed that JER1004 had been completely dissolved, and then the solution was cooled down to room temperature to obtain a JER1004-containing solution having a concentration of 50% by mass. This solution is taken as a curing agent solution E4.

### Preparation Example 5

To a container equipped with a stirring device, a thermometer and a condenser, 300 g of an epoxy resin having a structure of bisphenol A type (available from Japan Epoxy Resins Co., Ltd., grade name: JER828, epoxy equivalent: 135 g/eq, having 2 epoxy groups in one molecule, liquid at ordinary temperature) and 300 g of γ-butyrolactone (available from Mitsubishi Chemical Corporation) were added, and stirring was started. With continuing stirring, the temperature in the container was raised to 70° C. by the use of an oil bath. After the internal temperature of the container was raised to 70° C., stirring was continued for 30 minutes. Thereafter, it was confirmed that JER828 had been completely dissolved, and then the solution was cooled down to room temperature to obtain a JER828-containing solution having a concentration of 50% by mass. This solution is taken as a curing agent solution E5.

### Preparation Example 6

To a container equipped with a stirring device, a thermometer and a condenser, 300 g of an epoxy resin having a biphenyl structure (available from Japan Epoxy Resins Co., Ltd., grade name: JER YL6121H, epoxy equivalent: 175 g/eq, having 2 epoxy groups in one molecule, solid at ordinary temperature) and 300 g of γ-butyrolactone (available from Mitsubishi Chemical Corporation) were added, and stirring was started. With continuing stirring, the temperature in the container was raised to 70° C. by the use of an oil bath. After the internal temperature of the container was raised to 70° C., stirring was continued for 30 minutes. Thereafter, it was confirmed that JER YL6121H had been completely dissolved, and then the solution was cooled down to room temperature to obtain a JER YL6121H-containing solution having a concentration of 50% by mass. This solution is taken as a curing agent solution E6.

<Mixing of Main Agent Blend with Curing Agent Solution>

(Blending Example 1 for Thermosetting Composition)

In a plastic container, 117.16 g of the main agent blend C1 and 19.8 g of the curing agent solution E1 were placed. Mixing of them was carried out by stirring them at room temperature for 5 minutes using a spatula, whereby a thermosetting composition (referred to as a “thermosetting composition F1” hereinafter) was obtained.

(Blending Example 2 for Thermosetting Composition)

A thermosetting composition (referred to as a “thermosetting composition F2” hereinafter) was obtained in the same manner as in Blending Example 1 for thermosetting composition, except that the main agent blend C1 of the Blending Example 1 for thermosetting composition was replaced with the main agent blend C2.

(Blending Example 3 for Thermosetting Composition)

In a plastic container, 117.16 g of the main agent blend C1 and 11.7 g of the curing agent solution E2 were placed. Mixing of them was carried out by stirring them at room temperature for 5 minutes using a spatula, whereby a thermosetting composition (referred to as a “thermosetting composition F3” hereinafter) was obtained.

(Comparative Blending Example 1 for Thermosetting Composition)

In a plastic container, 117.16 g of the main agent blend C1 and 16.3 g of the curing agent solution E3 were placed. Mixing of them was carried out by stirring them at room temperature for 5 minutes using a spatula, whereby a thermosetting composition (referred to as a “thermosetting composition G1” hereinafter) was obtained.

(Comparative Blending Example 2 for Thermosetting Composition)

In a plastic container, 117.16 g of the main agent blend C1 and 65.8 g of the curing agent solution E4 were placed. Mixing of them was carried out by stirring them at room temperature for 5 minutes using a spatula, whereby a thermosetting composition (referred to as a “thermosetting composition G2” hereinafter) was obtained.

(Comparative Blending Example 3 for Thermosetting Composition)

In a plastic container, 117.16 g of the main agent blend C1 and 9.60 g of the curing agent solution E5 were placed. Mixing of them was carried out by stirring them at room temperature for 5 minutes using a spatula, whereby a thermosetting composition (referred to as a “thermosetting composition G3” hereinafter) was obtained.

(Comparative Blending Example 4 for Thermosetting Composition)

A thermosetting composition (referred to as a “thermosetting composition G4” hereinafter) was obtained in the same manner as in Comparative Blending Example 3 for thermosetting composition, except that the main agent blend C1 of the Comparative Blending Example 3 for thermosetting composition was replaced with the main agent blend C2.

(Comparative Blending Example 5 for Thermosetting Composition)

In a plastic container, 117.16 g of the main agent blend C1 and 12.44 g of the curing agent solution E6 were placed. Mixing of them was carried out by stirring them at room temperature for 5 minutes using a spatula, whereby a thermosetting composition (referred to as a “thermosetting composition G5” hereinafter) was obtained.

### Examples 1 to 3, Comparative Examples 1 to 5

Using the thermosetting compositions F1 to F3 and the thermosetting compositions G1 to G5, evaluation of an effect of inhibiting wiring disconnection of a flexible wiring board (MIT test), evaluation of warpage properties and evaluation of long-term electrical insulation reliability were carried out by the methods described below. The results are set forth in the later-described Table 1.

<Evaluation of Effect of Inhibiting Wiring Disconnection of Wiring Board (MIT Test)>

Onto a flexible wiring board obtained by tin plating of a substrate having a shape of a fine comb-like pattern (copper line width/copper line width=15 μm/15 μm) described in JPCA-ET01, said substrate having been produced by etching a flexible copper-clad laminate (manufactured by Sumitomo Metal Mining Co., Ltd., grade name: Esperflex US, thickness of copper: 8 μm, thickness of polyimide: 38 μm), the thermosetting composition F1 was applied by screen printing so that the thickness (thickness after drying) of the coating film from the polyimide surface would become 15 μm. The resulting wiring board with the coating film was placed in a hot air circulation type dryer at 80° C. for 30 minutes. Thereafter, it was further placed in a hot air circulation type dryer at 120° C. for 120 minutes to cure the coating film.

Using this specimen, a folding endurance test was carried out in accordance with JIS C-5016. As a tester, MIT Tester BE202 manufactured by Tester Sangyo Co., Ltd. was used, and the test was carried out under the conditions of a folding rate of 175 times/min, a load of 300 g, a folding angle of ±135° and a gripper tip R of 0.8. The number of folding times was increased by 10 times each time, and presence or absence of a crack of wiring was visually observed. When a crack occurred, the number of folding times was recorded. The result is set forth in Table 1.

Further, using the thermosetting compositions F2 and F3 and the thermosetting compositions G1 to G5, the same evaluation was carried out. The results are also set forth in Table 1.

<Evaluation of Warpage Properties>

The thermosetting composition F1 was applied onto a substrate by screen printing using a #100-mesh polyester screen. The resulting substrate with the coating film was placed in a hot air circulation type dryer at 80° C. for 30 minutes. Thereafter, it was further placed in a hot air circulation type dryer at 120° C. for 60 minutes to cure the coating film. As the substrate, a polyimide film [Kapton (registered trademark) 100EN, available from DuPont-Toray Co., Ltd.] having a thickness of 25 μm was used.

The cured coating film (referred to as a “cured film” hereinafter) was cut into 50 mmø with a circle cutter together with the substrate. The circularly cut cured film and substrate (referred to as a “specimen” hereinafter) undergo warpage in a convex or concave shape at the vicinity of the center thereof. After one hour, the specimen obtained by cutting with a circle cutter was allowed to stand still in the downward convex state, that is, it was allowed to stand still in such a manner that the vicinity of the center of the specimen was brought into contact with a horizontal plane (the cured film or the substrate was brought into contact with a horizontal plane). Then, the maximum height of warpage from the horizontal plane and the minimum height thereof were measured, and a mean value was determined. When the specimen is allowed to stand still in the downward convex state, a case where the cured film is positioned on the upper side of the polyimide film is represented by “+”, and a case where the cured film is positioned on the lower side is represented by “−”.

The result is set forth in Table 1.

Further, using the thermosetting compositions F2 and F3 and the thermosetting compositions G1 to G5, the same evaluation was carried out. The results are also set forth in Table 1.

<Evaluation of Long-Term Electrical Insulation Reliability>

Onto a flexible wiring board obtained by tin plating of a substrate having a shape of a fine comb-like pattern (copper line width/copper line width=15 μm/15 μm) described in JPCA-ET01, said substrate having been produced by etching a flexible copper-clad laminate (manufactured by Sumitomo Metal Mining Co., Ltd., grade name: Esperflex US, thickness of copper: 8 μm, thickness of polyimide: 38 μm), the thermosetting composition F1 was applied by screen printing so that the thickness (thickness after drying) of the coating film from the polyimide surface would become 15 μm. The resulting wiring board with the coating film was placed in a hot air circulation type dryer at 80° C. for 30 minutes. Thereafter, it was further placed in a hot air circulation type dryer at 120° C. for 120 minutes to cure the coating film.

To the resulting specimen, a bias voltage of 60 V was applied, and a steady-state temperature humidity test was carried out under the conditions of a temperature of 120° C. and a humidity of 85% RH by the use of MIGRATION TESTER MODEL MIG-8600 (manufactured by IMV Corporation). The resistance values of the specimen measured 50 hours and 100 hours after the start of the steady-state temperature humidity test are set forth in Table 1.

Further, using the thermosetting compositions F2 and F3 and the thermosetting compositions G1 to G5, the same evaluation was carried out. The results are also set forth in Table 1.

<Tensile Elastic Modulus>

Onto a fluororesin sheet having a thickness of 1 mm, the thermosetting composition F1 was applied so that the film thickness of the coating film after drying would become 40 to 60 μm. The resulting sheet with the coating film was placed in a hot air circulation type dryer at 80° C. for 30 minutes. Thereafter, it was further placed in a hot air circulation type dryer at 120° C. for 120 minutes to cure the coating film.

The fluororesin sheet was peeled off to obtain a cured product. The cured product was cut into a strip having a width of 10 mm and a length of 60 mm, and using the resulting cured film, a tensile test was carried out by the use of a small table-top tester EZGraph manufactured by Shimadzu Corporation under the conditions of a temperature of 25° C., a chuck-to-chuck distance of 30 mm and a pull rate of 5 mm/min. In the evaluation of the tensile elastic modulus, the number of samples (cured films) was 7 (n=7), and the tensile elastic modulus was expressed in terms of a mean value of n=5 excluding the maximum value and the minimum value.

TABLE 1

| | | | | | | Comp. | Comp. | Comp. | Comp. | Comp. |
|---|---|---|---|---|---|---|---|---|---|---|
| | | Unit | Ex. 1 | Ex. 2 | Ex. 3 | Ex. 1 | Ex. 2 | Ex. 3 | Ex. 4 | Ex. 5 |
| Thermosetting composition used | | — | F1 | F2 | F3 | G1 | G2 | G3 | G4 | G5 |
| Evaluation of effect of | | Number | 150 times | 150 times | 150 times | 150 times | 150 times | 70 times | 70 times | 70 times |
| inhibiting wiring disconnection | | of times | or more | or more | or more | or more | or more | | | |
| Evaluation of warpage properties | | mm | −1.0 | −1.0 | 1.0 | +5.0 | +3.0 | −2.0 | −2.0 | 0.0 |
| | | | | | | or more | | | | |
| Evaluation of | Resistance | Ω | 6 × 10\hat{ }8 | 6 × 10\hat{ }8 | 6 × 10\hat{ }8 | 6 × 10\hat{ }8 | 6 × 10\hat{ }8 | 6 × 10\hat{ }8 | 6 × 10\hat{ }8 | 6 × 10\hat{ }8 |
| long-term | values after 50 | | | | | | | | | |
| electrical | hours from the | | | | | | | | | |
| insulation | start | | | | | | | | | |
| reliability | Resistance | | 5 × 10\hat{ }8 | 5 × 10\hat{ }8 | 5 × 10\hat{ }8 | 5 × 10\hat{ }8 | 3 × 10\hat{ }3 | 5 × 10\hat{ }8 | 5 × 10\hat{ }8 | 5 × 10\hat{ }8 |
| | values after 100 | | | | | | | | | |
| | hours from the | | | | | | | | | |
| | start | | | | | | | | | |

| | | | | | | | | | |
|---|---|---|---|---|---|---|---|---|---|
| Tensile elastic modulus | GPa | 0.8 | 0.8 | 1.5 | 3.0 | 2.5 | 0.3 | 0.3 | 0.4 |

From Table 1, it can be seen that when the tensile elastic modulus is high, the disconnection inhibition effect is high. On the other hand, it can be seen that if the tensile elastic modulus is too high (exceeds 2.0 GPa), warpage is high. If the warpage is high, negative influences, such as transportation failure, misregistration, etc. in the steps for producing a flexible wiring board having an insulating film, are exerted.

1. A thermosetting composition for forming an insulating film, by curing the composition, on a flexible wiring board comprising a wiring pattern formed on a flexible substrate, wherein a cured product obtained by curing the composition has a tensile elastic modulus of 0.5 to 2.0 GPa.

2. The thermosetting composition as claimed in claim 1, wherein the flexible wiring board has a line width of not more than 20 μm.

3. The thermosetting composition as claimed in claim 1, which contains polyurethane (a) having a functional group having reactivity to an epoxy group and a carbonate bond, inorganic fine particles and/or organic fine particles (b) and a compound (c) having two or more epoxy groups in one molecule.

4. The thermosetting composition as claimed in claim 3, wherein the functional group having reactivity to an epoxy group in the polyurethane (a) is at least one functional group selected from the group consisting of a carboxyl group, an isocyanate group, a hydroxyl group and a cyclic acid anhydride group.

5. The thermosetting composition as claimed in claim 3, wherein the compound (c) has an aromatic ring structure and/or an alicyclic structure.

6. The thermosetting composition as claimed in claim 5, wherein the compound (c) has a tricyclodecane structure and an aromatic ring structure.

7. A cured product obtained by thermally curing the thermosetting composition as claimed in claim 1.

8. A flexible wiring board having an insulating film, wherein a wiring pattern-side surface of a flexible wiring board comprising a wiring pattern formed on a flexible substrate is at least partially covered with an insulating film composed of the cured product as claimed in claim 7.

9. A process for producing a flexible wiring board having an insulating film, having the steps of:
applying the thermosetting composition as claimed in claim 1 onto a wiring pattern of a flexible wiring board comprising the wiring pattern formed on a flexible substrate, by a printing method to form a printed film on the pattern, and
heating the printed film at 80 to 130° C. to cure the film and to thereby form an insulating film from the printed film.

10. The process for producing a flexible wiring board having an insulating film as claimed in claim 9, wherein the wiring pattern has been subjected to tin plating.

11. The thermosetting composition as claimed in claim 2, which contains polyurethane (a) having a functional group having reactivity to an epoxy group and a carbonate bond, inorganic fine particles and/or organic fine particles (b) and a compound (c) having two or more epoxy groups in one molecule.

12. The thermosetting composition as claimed in claim 11, wherein the functional group having reactivity to an epoxy group in the polyurethane (a) is at least one functional group selected from the group consisting of a carboxyl group, an isocyanate group, a hydroxyl group and a cyclic acid anhydride group.

13. A process for producing a flexible wiring board having an insulating film, having the steps of:
applying the thermosetting composition as claimed in claim 2 onto a wiring pattern of a flexible wiring board comprising the wiring pattern formed on a flexible substrate, by a printing method to form a printed film on the pattern, and
heating the printed film at 80 to 130° C. to cure the film and to thereby form an insulating film from the printed film.
